(19) United States
(12) Patent Application Publication
(10) Pub. No.: US 2021/0013499 A1
(43) Pub. Date: Jan. 14, 2021

(54) SILICON-GRAPHITE COMPOSITE ELECTRODE ACTIVE MATERIAL FOR LITHIUM SECONDARY BATTERY, ELECTRODE AND SECONDARY BATTERY PROVIDED THEREWITH, AND MANUFACTURING METHOD FOR SUCH A SILICON-GRAPHITE COMPOSITE ELECTRODE ACTIVE MATERIAL

(71) Applicant: LIVENERGY CO., LTD., Busan (KR)

(72) Inventor: Hong Soo JIN, Busan (KR)

(73) Assignee: LIVENERGY CO., LTD., Busan (KR)

(21) Appl. No.: 17/034,960

(22) Filed: Sep. 28, 2020

Related U.S. Application Data
(63) Continuation of application No. PCT/KR2019/011870, filed on Sep. 11, 2019.

(30) Foreign Application Priority Data
May 17, 2019 (KR) 10-2019-0058161

(51) Int. Cl. H01M 4/36; H01M 4/38; H01M 4/587; H01M 10/0525

(52) U.S. Cl. CPC H01M 4/366; H01M 4/386; H01M 2004/027; H01M 10/0525; H01M 4/587

(57) ABSTRACT

A silicon-graphite composite electrode active material used for a secondary battery is provided. The silicon-graphite composite electrode active material may be formed using silicon-graphite composites that silicon is mixed in graphite material as unit powder. The silicon-graphite composite may be formed such that the silicon is located inside the graphite material and is not exposed to an outer surface of the graphite material.

### CROSS-REFERENCE TO RELATED APPLICATIONS

This application is a continuation of International Application No. PCT/KR2019/011870 filed on Sep. 11, 2019 which claims priority to Korean Patent Application No. 10-2019-0058161 filed on May 17, 2019, the entire contents of which are herein incorporated by reference.

### TECHNICAL FIELD

The present invention relates to an electrode active material for lithium secondary battery, an electrode and a secondary battery including the same, and a manufacturing method for such a silicon-graphite composite electrode active material, and more particularly, to an electrode active material, which is capable of providing a high capacity and high-efficiency charge-discharge property by mixing graphite and silicon, an electrode and a secondary battery including the same, and a manufacturing method for the electrode active material.

### BACKGROUND ART

In recent years, a lithium secondary battery has attracted attention as a power source for driving electronic devices. Such a lithium secondary battery has been extensively used in various fields from IT devices such as mobile phones to electric vehicles and energy storage devices.

The structure of the lithium secondary battery has been variously developed as application fields and demands of the lithium secondary battery are increased. Various researches and developments have been actively conducted to improve capacity, lifespan, performance, safety, and the like of the battery.

As an example, graphite-based material has been conventionally widely used as an electrode active material (negative electrode active material) of the lithium secondary battery. However, graphite has a capacity per unit mass of about 372 mAh/g, which causes a limit in increasing the capacity of the secondary battery. This makes it is difficult to sufficiently improve the performance of the secondary battery. For this reason, in recent years, researches have been conducted to replace the graphite-based material with a substance that forms an electrochemical alloy with lithium, such as silicon (Si), tin (Sn), antimony (Sb), aluminum (Al) or the like.

However, these substances have a property that volumetric expansion/shrinkage occurs in the course of forming an electrochemical alloy with lithium at the time of charge-discharge operation. Such a volume change due to the charge-discharge operation causes a volumetric expansion of an electrode, thereby degrading cycle characteristics of the secondary battery. As a result, the electrode active material manufactured using these substances has not yet been substantially commercialized.

For example, silicon is getting a lot of attention as an electrode active material for secondary battery, which can replace the graphite-based material. Silicon can absorb 4.4 lithium ions per one silicon particle, and thus can provide a high capacity of the secondary battery. However, the volume of silicon is expanded by a factor of about 4 times in the course of absorbing lithium ions (for reference, graphite which has been conventionally widely used as an electrode active material exhibits an expansion rate of about 1.2 times at the time of charge-discharge operation). Accordingly, as the charge-discharge of the secondary battery repeats, the expansion of the electrode may be increased and the cycle characteristic of the secondary battery may be rapidly degraded.

In order to solve this problem, techniques for forming an electrode active material by mixing silicon in carbon-based material such as graphite or the like have recently been proposed. For example, Patent Documents 1 and 2 disclose techniques for forming a silicon layer on carbon-based material such as graphite or the like to improve the performance of the secondary battery.

Specifically, Patent Document 1 discloses a technique for forming a silicon coating layer on a surface of carbon-based material such as graphite or the like to enhance the capacity of the secondary battery and alleviate deterioration in cycle characteristics of the secondary battery due to expansion/shrinkage of silicon, compared to the conventional electrode active material formed of graphite material. However, the electrode active material disclosed in Patent Document 1 has a structure in which the silicon coating layer is provided on an outer surface of the carbon-based material. Accordingly, the external silicon layer may be significantly expanded and shrunk at the time of charge-discharge operation, and the electrode active material may be electrically short-circuited from the electrode or the surface of the electrode active material may be pulverized to accelerate side reaction with electrolyte. That is, the electrode active material disclosed in Patent Document 1 still has a problem of degrading the performance of the secondary battery.

In the meantime, Patent Document 2 discloses a technique for forming a silicon coating layer inside carbon-based material such as graphite or the like to improve the performance of an electrode active material. Specifically, Patent Document 2 discloses a technique for forming the silicon coating layer in cavities of the carbon-based material by spheroidizing the carbon-based material to form cavities therein and then depositing the silicon coating layer through a chemical vapor deposition (CVD). However, even in the case of the technique disclosed in Patent Document 2, the silicon coating layer is naturally deposited not only in the cavities formed inside the carbon-based material but also on an outer surface of the carbon-based material in the process of locating the carbon-based material, which has cavities formed therein by the spheroidization process, into a reaction chamber and then supplying a raw material gas into the reaction chamber to deposit the silicon coating layer. The silicon coating layer formed on the outer surface of the carbon-based material as described above is repeatedly expanded/shrunk at the time of charge-discharge operation. This may be a cause of degrading the cycle characteristics of the secondary battery as the electrode active material disclosed in Patent Document 1.

In order to solve the above problem, Patent Documents 1 and 2 disclose a configuration of forming a carbon layer or a conductive coating layer on the surface of the electrode active material in which the silicon layer is formed on the carbon-based material. However, such a thin film coating layer may be broken in the course of rolling the electrode active material to form an electrode, and silicon may be exposed through the broken surface. The silicon exposed to the outside may accelerate side reaction with electrolyte, which may a cause of degrading the performance and lifespan of the secondary battery.

Therefore, in the field of secondary batteries, there is still a demand for an electrode active material and a manufacturing method thereof, which are capable of improving the capacity of the secondary battery and ensuring excellent cycle characteristics.

### PRIOR ART DOCUMENTS

Patent Document 1: Korean Patent No. 10-1628873 (Registration Date: Jun. 2, 2016)
Patent Document 2: Korean Patent No. 10-1866004 (Registration Date: Jun. 1, 2018)

### SUMMARY

### Technical Problem

The present invention is provided to solve the aforementioned problems related to the conventional electrode active material for secondary battery. The present invention is to provide an electrode active material for secondary battery, which is capable of providing excellent cycle characteristics and improving the capacity of the secondary battery, an electrode and a secondary battery including the same, and a manufacturing method for such an electrode active material.

### Technical Solution

Representative configurations of the present invention for achieving the above-mentioned object are as follows.

According to one embodiment of the present invention, a silicon-graphite composite electrode active material used for secondary battery is provided. The silicon-graphite composite electrode active material according to one embodiment of the present invention may be formed using silicon-graphite composites that silicon is mixed in graphite material as unit powder. Wherein, the silicon-graphite composite may be formed such that the silicon is located inside the graphite material and is not exposed to an outer surface of the graphite material.

According to one embodiment of the present invention, the silicon included in the silicon-graphite composite may be configured such that 90 wt % or more of the silicon with respect to a total weight of the silicon is located at a depth of 200 nm or more from the outer surface of the silicon-graphite composite.

According to one embodiment of the present invention, the silicon included in the silicon-graphite composite may be configured such that all the silicon is located at a depth of 200 nm or more from the outer surface of the silicon-graphite composite.

According to one embodiment of the present invention, the silicon included in the silicon-graphite composite may be configured to be located at a depth of 1 μm or more from the outer surface of the silicon-graphite composite.

According to one embodiment of the present invention, the silicon included in the silicon-graphite composite may be configured to be located at a depth of 3 μm or more from the outer surface of the silicon-graphite composite.

According to one embodiment of the present invention, the silicon included in the silicon-graphite composite may exceed 10 wt % with respect to a total weight of the silicon-graphite composite.

According to one embodiment of the present invention, the silicon included in the silicon-graphite composite may exceed 15 wt % with respect to the total weight of the silicon-graphite composite.

According to one embodiment of the present invention, the silicon may be deposited on the graphite material using a raw material gas containing at least one selected from a group consisting of SiH₄, Si₂H₆, Si₃H₈, SiCl₄, SiHCl₃, Si₂Cl₆, SiH₂Cl₂ and SiH₃Cl.

According to one embodiment of the present invention, the silicon may be deposited on the graphite material as a thin film layer having a thickness of 20 nm to 500 nm.

According to one embodiment of the present invention, the silicon may be deposited on the graphite material by supplying the raw material gas containing at least one selected from the group consisting of SiH₄, Si₂H₆, Si₃H₈, SiCl₄, SiHCl₃, Si₂Cl₆, SiH₂Cl₂ and SiH₃Cl, together with an assist gas containing at least one selected from a group consisting of carbon, nitrogen and germanium.

According to one embodiment of the present invention, the silicon deposited on the graphite material may further include the least one selected from the group consisting of carbon, nitrogen and germanium.

According to one embodiment of the present invention, the thin film silicon layer formed on the silicon-graphite composite may be formed of amorphous silicon particles or quasi-crystalline silicon particles.

According to one embodiment of the present invention, the silicon-graphite composite electrode active material used for secondary battery may further comprise a surface coating layer formed on an outer peripheral surface of the silicon-graphite composite.

According to one embodiment of the present invention, a negative electrode for lithium secondary battery comprising the aforementioned silicon-graphite composite electrode active material is provided.

According to one embodiment of the present invention, a lithium secondary battery comprising a positive electrode; the aforementioned negative electrode, and an electrolyte provided between the positive electrode and the negative electrode is provided.

According to one embodiment of the present invention, a method of manufacturing silicon-graphite composite electrode active material for secondary battery is provided. The manufacturing method for the silicon-graphite composite electrode active material according to one embodiment of the present invention may comprise a graphite base material preparation step of preparing graphite material used as base material; a silicon layer formation step of forming a silicon layer on the graphite base material; a reassembling step of spheroidizing and mechanically assembling the graphite on which the silicon layer is formed such that the silicon is located only inside the graphite.

According to one embodiment of the present invention, in the silicon layer formation step, the silicon layer may be deposited and formed as a thin film layer on the graphite having a plate shape through a chemical vapor deposition.

According to one embodiment of the present invention, in the silicon layer formation step, the silicon layer may be formed using a raw material gas containing at least one selected from a group consisting of SiH₄, Si₂H₆, Si₃H₈, SiCl₄, SiHCl₃, Si₂Cl₆, SiH₂Cl₂ and SiH₃Cl.

According to one embodiment of the present invention, in the silicon layer formation step, the silicon layer may be formed at a thickness of 2 nm to 500 nm on the graphite base material.

According to one embodiment of the present invention, in the silicon layer formation step, the silicon layer may be deposited on the graphite base material by supplying the raw material gas together with an assist gas.

According to one embodiment of the present invention, the assist gas may include at least one selected from a group consisting of carbon, nitrogen and germanium.

According to one embodiment of the present invention, the reassembling step may be performed by locating the graphite base material on which the silicon layer is formed into a spheroidization equipment and then mechanically-reassembling the graphite base material on which the silicon layer is formed while rotating the spheroidization equipment at a high speed.

According to one embodiment of the present invention, the reassembling step may be performed by locating the graphite base material on which the silicon layer is formed into a spheroidization equipment and rotating the spheroidization equipment at a high speed and then supplying additional graphite material into the spheroidization equipment and mechanically-reassembling the graphite base material on which the silicon layer is formed while rotating the spheroidization equipment at the high speed.

According to one embodiment of the present invention, the method may further comprise a surface coating step of forming an outer coating layer on the surface of the silicon-graphite composite, after the reassembling step.

According to one embodiment of the present invention, the method may further comprise a surface modification step of modifying the surface of the graphite base material between the graphite base material preparation step and the silicon layer formation step.

According to one embodiment of the present invention, the graphite base material prepared in the graphite base material preparation step may be a natural or artificial graphite having a plate shape and a thickness of 2 μm to 20 μm.

In some embodiments, additional components may be included in the electrode active material, the electrode (negative electrode) and the secondary battery including the same, and the manufacturing method for the electrode active material according to the present invention, without departing from the spirit and scope of the present invention.

### Advantageous Effects

An electrode active material according to one embodiment of the present invention is formed to have a structure of silicon-graphite composite in which silicon is included in graphite material, and is configured such that the silicon included in the silicon-graphite composite is located only inside the graphite material and do not exist on an outer surface of the graphite material. Thus, the capacity and performance of the secondary battery can be improved by the silicon material included in the electrode active material. Further, it is possible to eliminate a problem in that the volume of the electrode is expanded due to the expansion/shrinkage of silicon, and greatly suppress a possibility that the electrode active material is electrically short-circuited from the electrode. Furthermore, it is possible to solve a problem that the side reaction with electrolyte is accelerated due to the silicon exposed to the surface of the electrode active material. As a result, the present invention may provide an effect of greatly improving the performance and lifespan of the secondary battery.

### DESCRIPTION OF DRAWINGS

FIG. 1 illustrates an exemplary photograph of an electrode active material for secondary battery according to one embodiment of the present invention, which is observed with a scanning electron microscope (SEM).

FIG. 2A illustrates exemplary photographs of a plate-shape graphite which can be used for manufacturing the electrode active material for secondary battery according to one embodiment of the present invention, which are observed with a scanning electron microscope (SEM).

FIG. 2B illustrates exemplary photographs of a plate-shape graphite which can be used for manufacturing the electrode active material for secondary battery according to one embodiment of the present invention, which are observed with a scanning electron microscope (SEM).

FIG. 3 illustrates examples of a state in which a silicon coating layer is formed on the plate-shape graphite of FIGS. 2A and 2B.

FIG. 4 illustrates examples of an electrode active material obtained in a process of spheroidizing the plate-shape graphite on which the silicon coating layer is formed.

FIG. 5 illustrates examples specific surface area characteristics of graphite before and after a surface modification process.

FIG. 6 illustrates examples of a silicon-graphite composite according to one embodiment of the present invention after the spheroidization process.

FIG. 7 illustrates examples of a cross-sectional structure of the silicon-graphite composite (after the spheronization process) according to one embodiment of the present invention.

FIG. 8A illustrates examples of a cross-sectional structure of an electrode plate obtained by rolling a conventional silicon-graphite composite in which a spherical graphite is coated with a silicon layer and then a surface of the silicon layer is coated with a petroleum-based pitch.

FIG. 8B illustrates a cross-sectional structure of a silicon-graphite composite according to one embodiment of the present invention.

FIG. 9 illustrates an example of electrochemical performance test results of the conventional silicon-graphite composite and the silicon-graphite composite according to one embodiment of the present invention.

FIG. 10A illustrates an example of an electrochemical performance test result of the conventional silicon-graphite composite and the silicon-graphite composite according to one embodiment of the present invention.

FIG. 10B illustrates an example of an electrochemical performance test result of the conventional silicon-graphite composite and the silicon-graphite composite according to one embodiment of the present invention.

FIG. 10C illustrates an example of an electrochemical performance test result of the conventional silicon-graphite composite and the silicon-graphite composite according to one embodiment of the present invention.

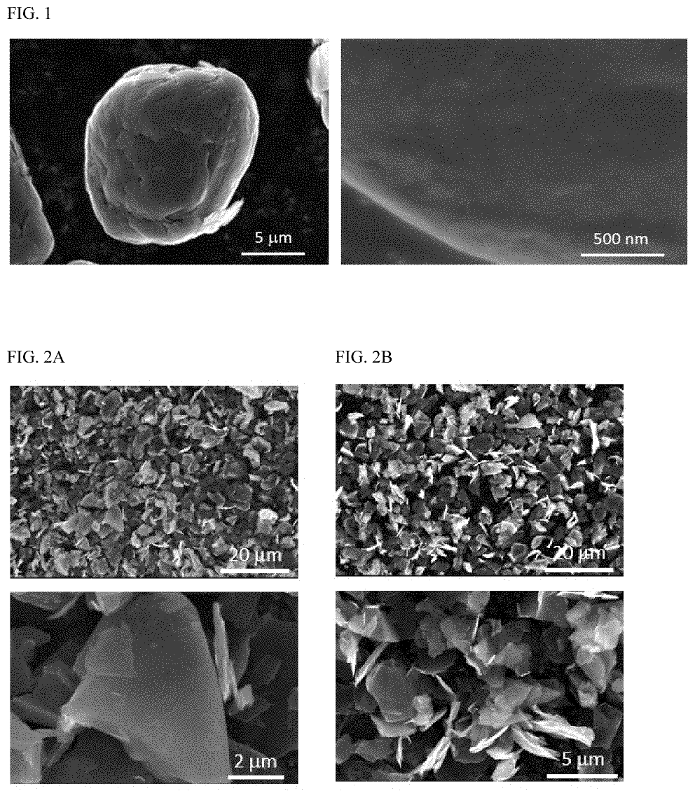

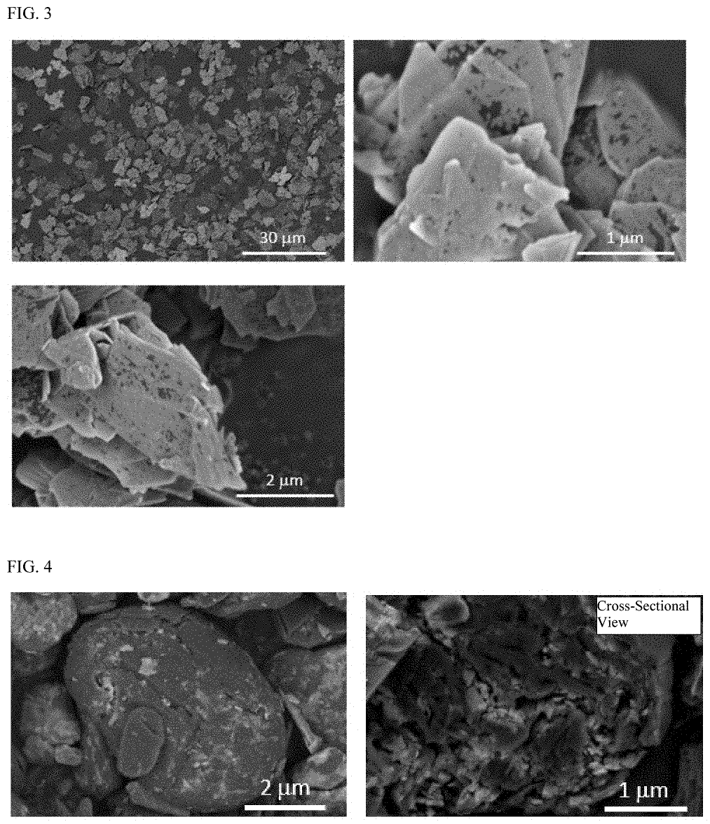

### DETAILED DESCRIPTION

Hereinafter, preferred embodiments of the present invention will be described in detail with reference to the appended drawings to such an extent that the present invention can be readily practiced by one of ordinary skill in the art.

Detailed descriptions of parts irrelevant to the present invention will be omitted for the purpose of more clearly describing the present invention. Throughout the specification, the same components will be described using same reference numerals. In addition, the shapes and sizes of the respective components shown in the drawings are arbitrarily shown for the sake of convenience in description, and hence the present invention is not necessarily limited to the illustrated shapes and sizes. That is, it should be understood that specific shapes, structures, and characteristics described in the specification may be modified in various embodiments without departing from the spirit and scope of the present invention, and positions or arrangements of individual components may be modified without departing from the spirit and scope of the present invention. Therefore, detailed descriptions to be described below should be construed as non-limitative senses, and the scope of the present invention should be understood to include appended claims and their equivalents.

Electrode Active Material according to the present invention, and Electrode and Secondary Battery including the same.

According to one embodiment of the present invention, a silicon-graphite composite electrode active material (negative electrode active material) in which silicon is mixed in graphite material may be provided.

As described above, the graphite material that has been conventionally used as an electrode active material for secondary battery has problems such as capacity limitation and a degradation in output characteristics at the time of high-speed charge. The silicon material has low electrical conductivity. Further, the silicon material has a problem of causing significant volumetric expansion at the time of charge-discharge. This causes serious damage to the electrode active material and the electrode plate. Such a damage significantly deteriorates the cycle characteristic of the secondary battery.

In contrast, the electrode active material according to one embodiment of the present invention is formed to have a composite structure in which silicon is mixed in graphite material. Accordingly, the battery capacity can be significantly improved as compared with the conventional electrode active material made of graphite. As will be described later, the silicon included in the electrode active material is configured such that the great majority thereof is located inside the graphite material without being exposed to an outer surface of the graphite material (preferably, the silicon is configured to be located significantly deeply inside the graphite material). This prevents a problem that the silicon is exposed to the electrolyte in the process of forming the electrode with the electrode active material through a rolling process and thus a side reaction occurs. Further, the silicon is expanded and shrunk only inside the graphite material, which makes it possible to suppress the lifespan shortening and performance degradation of the secondary battery due to the volumetric expansion of silicon.

Specifically, the electrode active material according to one embodiment of the present invention may be configured to be formed using silicon-graphite composites in which silicon material is mixed in graphite material (see powder mass illustrated in an enlarged scale in FIG. 1).

Such a silicon-graphite composite may function as a unit powder body for forming the electrode active material for secondary battery, and may have a configuration that the silicon is formed on the graphite material as a thin film layer or the like. Depending on the capacity of the secondary battery, a number of silicon-graphite composites may collect to form the electrode active material.

According to one embodiment of the present invention, the silicon may be deposited and formed on the graphite material by a method such as a chemical vapor deposition (CVD) or the like. The silicon may be located only inside the graphite material without being exposed to the outer surface of the graphite material.

As described above, when the silicon-graphite composite, which serves as a unit powder for forming an electrode active material, is formed such that the silicon is located inside the graphite material without being exposed to the outer surface of the silicon-graphite composite, it possible to suppress damage of the electrode plate due to the expansion/shrinkage of the silicon exposed to the outside, and it is possible prevent acceleration of the side reaction, which is caused when the silicon exposed to the outside are brought into contact with the electrolyte. Thus, the performance and lifespan of the secondary battery can be significantly improved.

According to one embodiment of the present invention, the silicon included in the silicon-graphite composite that constitutes the electrode active material may be configured to exceed 10 wt %, preferably 15 wt %, with respect to a total weight of the silicon-graphite composite. Silicon can provide a capacity larger than that of graphite. Thus, the capacity of the secondary battery can be further increased as a large amount of silicon is included in the electrode active material. However, the silicon included in the electrode active material may significantly degrade the cycle characteristics of the secondary battery due to the volumetric expansion generated at the time of charge-discharge. Thus, there may be a limit in increasing the amount of silicon to be added to the electrode active material. For example, the conventional silicon-graphite composite electrode active material is configured such that only a small amount of silicon is included in the electrode active material to address the problem of degradation in cycle characteristic of the secondary battery due to the expansion/shrinkage of silicon. However, the electrode active material according to one embodiment of the present invention is configured such that the silicon is located inside the graphite material and is not exposed outward of the graphite material. Thus, even if silicon of more than 1 Owt % (more preferably, more than 15 wt %) is included in the electrode active material, surface crack due to the expansion/shrinkage of silicon can be suppressed. Accordingly, a relatively large amount of silicon may be mixed in the silicon-graphite composite and the capacity of the secondary battery may be further improved.

According to one embodiment of the present invention, the silicon included in the silicon-graphite composite that constitutes the electrode active material may be formed to have amorphous silicon particles or quasi-crystalline silicon particles. The amorphous or quasi-crystalline silicon particles have the advantages that they have not directivity of absorbing lithium unlike a crystalline silicon particle and thus undergo uniform volumetric expansion, and a lithium movement rate is high and little stress or strain is applied in absorption or desorption of lithium compared to the crystalline silicon, thus maintaining a stable structure. Accordingly, if the silicon is formed with amorphous or quasi-crystalline particles, it is possible to prevent a problem in that the secondary battery is damaged by the volumetric expansion of silicon even if a relatively larger amount of silicon is included in the electrode active material.

According to one embodiment of the present invention, in the silicon-graphite composite that constitutes the electrode active material, the silicon may be configured such that 90 wt % or more of silicon with respect to the total weight of the silicon is located at a depth of at least 200 nm or more from the outer surface of the silicon-graphite composite, more preferably all silicon is located at a depth of at least 200 nm or more from the outer surface.

When the silicon is located more deeply inside the graphite material in the silicon-graphite composite that constitutes the electrode active material as described above, it is possible to efficiently prevent occurrence of the side reaction, which is caused when the silicon exposed to the outer surface is brought into contact with the electrolyte, thus further improving the performance and the lifespan of the secondary battery.

In order to further increase such effects, the silicon-graphite composite according to one embodiment of the present invention may be configured to be located at a depth of 1 μm or more, more preferably 3 μm or more, from the surface of the silicon-graphite composite.

Furthermore, the electrode active material according to one embodiment of the present invention may be configured such that a thickness or distance between the outermost silicon and the outer surface of the silicon-graphite composite is larger than a thickness or distance from the center portion of the silicon-graphite composite to the outermost silicon. With such a configuration, the electrode active material according to one embodiment of the present invention may be formed to have a structure of core-shell shape in which graphite material surrounds around a core in which silicon and graphite are mixed. Thus, the silicon can be stably at a deep position inside graphite.

According to one embodiment of the present invention, a surface coating layer may be further formed on the outer peripheral surface of the silicon-graphite composite that constitutes the electrode active material. The surface coating layer formed on the outer peripheral surface of the silicon-graphite composite may perform a function of providing an electron transfer path to improve electrical conductivity and suppressing a change in volume of silicon at the time of charge-discharge to improve the stability of the electrode plate.

According to one embodiment of the present invention, the surface coating layer formed on the outer peripheral surface of the silicon-graphite composite may be formed of another carbon material (for example, at least one carbon material selected from a group consisting of coal tar pitch, petroleum-based pitch, epoxy resin, phenolic resin, polyvinyl alcohol, polyvinyl chloride, ethylene, acetylene, and methane), which is different from the graphite that constitutes the silicon-graphite composite.

However, the surface coating layer is not necessarily essential. The electrode active material may be formed without the surface coating layer. Alternatively, an additional coating layer (conductive coating layer or the like) may be formed in addition to the aforementioned surface coating layer made of the carbon material.

Further, according to one embodiment of the present invention, an electrode (negative electrode) and a secondary battery including the aforementioned electrode active material may be provided.

Specifically, the electrode and the secondary battery according to one embodiment of the present invention may comprise the electrode active material formed of the above-described silicon-graphite composite. The silicon-graphite composite that forms the electrode active material may be formed to have a structure in which silicon is mixed in graphite material as described above.

With such a configuration, since the silicon-graphite composite may be formed to have a structure in which the silicon is located inside the graphite material so that they are mixed with each other, it is possible to achieve an increase in capacity of the battery with the silicon, and efficiently suppress the performance degradation and lifespan shortening of the electrode and the secondary battery due to the volumetric expansion of silicon and the contact of the silicon with the electrolyte.

In the meantime, the electrode active material according to one embodiment of the present invention may be used alone to form the electrode of the secondary battery. Further, the electrode active material according to one embodiment of the present invention may be mixed with the conventional electrode active material (for example, an electrode active material formed of graphite-based material) to form an electrode active material for secondary battery.

As described above, the electrode active material according to one embodiment of the present invention can control the problem such as the electrode damage caused by the volumetric expansion of silicon in a stable manner. Thus, a relatively large amount of silicon can be included in the electrode active material as compared with the conventional electrode active material, which makes it possible to sufficiently increase the battery capacity. Accordingly, even if the electrode active material according to one embodiment of the present invention is used in combination with the conventional electrode active material, it is possible to provide a significant capacity improvement effect compared with the conventional electrode active material. Furthermore, by using the electrode active material according to this embodiment in combination with the conventional electrode active material such as an electrode active material formed of graphite-based material, it is possible to more efficiently control the problem of the volumetric expansion of silicon.

Manufacturing method for the electrode active material according to the present invention.

According to one embodiment of the present invention, there is provided a method of manufacturing a silicon-graphite composite electrode active material in which silicon is added to graphite material (specifically, a silicon-graphite composite that constitutes an electrode active material).

According to one embodiment of the present invention, the manufacturing method for the electrode active material (the silicon-graphite composite that constitutes the electrode active material) may comprise (i) a graphite base material preparation step of preparing graphite material (e.g., a plate-shape graphite), (ii) a silicon layer forming step of forming a silicon layer on the prepared graphite base material, (iii) a reassembling step of spheroidizing the graphite, on which the silicon layer is formed, and mechanically assembling the graphite, on which the silicon layer is formed, such that silicon is located only inside the graphite.

The graphite base material preparation step is a step of preparing the graphite base material, which is a base material of the silicon-graphite composite according to one embodiment of the present invention. The base material may be a natural or artificial graphite having a plate-shape structure, and may be formed of material having a particle size of, for example, 2 μm to 20 μm.

The silicon layer formation step is a step of coating silicon material with the plate-shape graphite base material to increase the capacity of the electrode active material, and may be performed through a chemical vapor deposition (CVD) or the like.

Specifically, the formation of the silicon layer may be performed by supplying a silicon-containing raw material gas into a high-temperature reaction chamber such that the silicon is deposited on the graphite base material. For example, the formation of the silicon layer may be performed by supplying the raw material gas such as SiH₄, Si₂H₆, Si₃H₈, SiCl₄, SiHCl₃, Si₂Cl₆, SiH₂Cl₂ and SiH₃Cl, or the like into the reaction chamber heated to a temperature of 400° C. to 700° C., and depositing the silicon layer on the plate-shape graphite material.

According to the above method, the silicon layer may be formed on the graphite material at a relatively low temperature (temperature range from 400° C. to 700° C.). As a result, the silicon coating layer may be formed of amorphous silicon particles or quasi-crystalline silicon particles, rather than crystalline silicon particles.

Further, the formation of the silicon coating layer may be performed by additionally supplying an assist gas containing carbon, nitrogen, germanium, or the like together with the above-described raw material gas. As described above, when the silicon is deposited by further supplying the assist gas containing a substance such as carbon, nitrogen, germanium or the like, the substance such as carbon, nitrogen, germanium or the like is included in the silicon layer formed on the graphite material. Such a substance included in the deposited silicon layer can prevent silicon atoms contained in the silicon-graphite composite from being clustering and coarsening with each other, thus efficiently suppressing the volumetric expansion of silicon. Further, the electrical conductivity and/or the conductivity of lithium ions may be improved, and the electrode damage and the lifespan shortening of the secondary battery may be further alleviated.

According to one embodiment of the present invention, the silicon included in the silicon-graphite composite that constitutes the electrode active material may be may be configured to exceed 10 wt %, more preferably 15 wt %, with respect to the total weight of the silicon-graphite composite. Further, the silicon layer may be formed as a thin film layer having a thickness of 20 nm to 500 nm.

The reassembling step is a step of spheroidizing the graphite having the silicon layer formed thereon. In the reassembling step, the mechanical reassembling is performed such that the silicon layer deposited on the graphite base material is moved inside the graphite. As a result, the silicon-graphite composite in which the silicon layer is not exposed to the outer surface of the silicon-graphite composite, may be formed.

According to one embodiment of the present invention, the reassembling step may be performed by (i) locating the graphite base material on which the silicon layer is formed into a spheroidization equipment and then rotating the spheroidization equipment at a high speed to form the silicon-graphite composite, or (ii) locating the graphite base material on which the silicon layer is formed into the spheroidization equipment, followed by rotating the spheroidization equipment at a high speed, followed by providing additional graphite material into the spheroidization equipment after a predetermined period of time to form the spheroidized silicon-graphite composite. Through such a series of processes, the silicon-graphite composite in which the silicon layer is located only inside the graphite material and not exposed to the outer surface of the silicon-graphite composite can be formed.

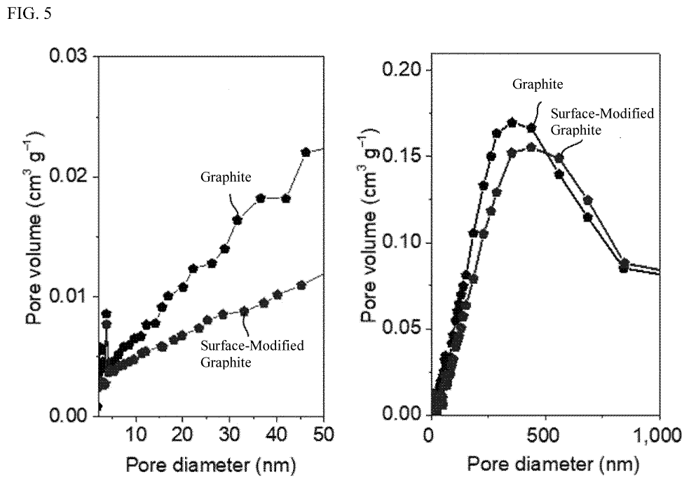

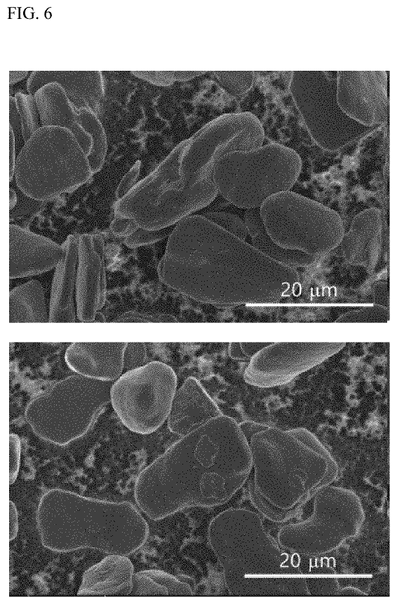

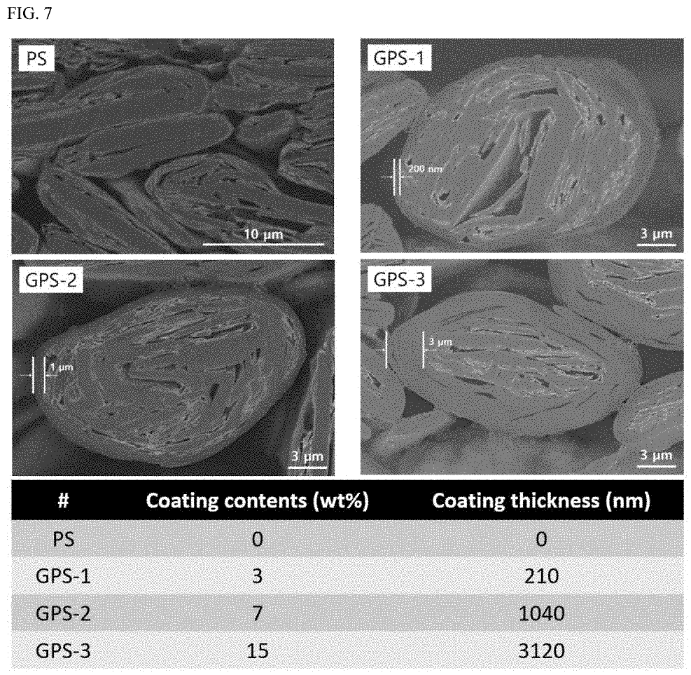

Further, according to one embodiment of the present invention, a surface modification step of modifying the surface of the graphite base material after preparing the graphite base material and before forming the silicon coating layer on the graphite base material. The surface modification is a step of filling fine pores formed in the graphite base material to prevent silicon from entering the fine pores, which are hard to secure a space to which the silicon expands. By performing the surface modification step, the fine pores having a size of 50 nm or less and formed in the graphite base material are filled with other amorphous or crystalline carbons so that the specific surface area of the graphite base material can be reduced (in the surface modification step, the fine pores formed in the graphite base material are filled with other amorphous or crystalline carbons so that the specific surface area can be reduced from a range of 2 to 10 m²/g to a range of 1 to 5 m²/g, as shown in FIG. 5). As a result, the silicon layer may be formed only on large cavities existing in the graphite base material and outside the graphite material. The silicon coating layer formed in the fine pores is not provided with a sufficient space necessary for the expansion of silicon and thus may cause cracks in the graphite base material. However, when the surface modification step is performed, it is possible to prevent the silicon coating layer from being formed in the fine pores, thus suppressing the graphite base material from being damaged.

According to one embodiment of the present invention, the surface modification step may be performed by coating precursor such as petroleum-based pitch, coal-based pitch, resin, asphalt, methane, ethylene, acetylene, or the like on a surface of the graphite base material. For example, the precursor such as petroleum-based pitch, coal-based pitch, resin, asphalt, or the like may be coated on the graphite base material using a rotary furnace, an atmosphere furnace or the like. The precursor coating may be performed in a state of holding the graphite material for two or more hours in an inert gas atmosphere, such as N₂, Ar, or the like, at a temperature ranging from 600° C. to 1,000° C. In the meantime, the precursor such as methane, ethylene, acetylene, or the like may be coated on the graphite base material with a vapor deposition apparatus, a rotary furnace or the like. For example, the precursor may be coated on the surface of the graphite material by flowing the precursor to the plate-shape graphite with a flow rate of 3 L to 8 L per minute at a temperature ranging from 800° C. to 1,000° C.

The silicon-graphite composite electrode active material according to one embodiment of the present invention, which is manufactured in the above manner, is formed in a state that the silicon is stably located inside the graphite material (more preferably, the silicon is located deeply inside the graphite material). This makes it possible to reduce the risk of causing a side reaction due to the contact of the silicone with the electrolyte, and further achieve the performance improvement and the prolonged lifespan of the electrode and the secondary battery.

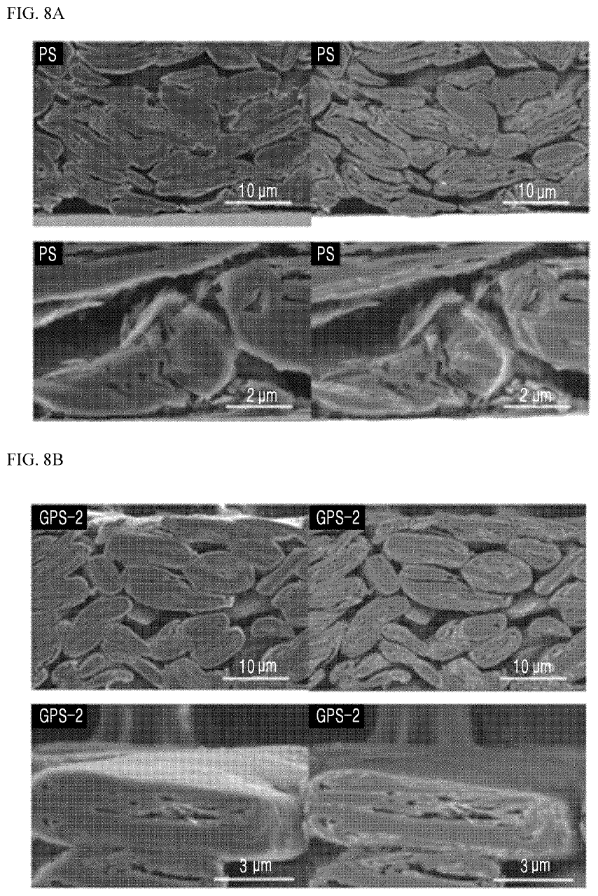

For example, in the conventional silicon-graphite composite in which a silicon layer is deposited on a surface of a graphite material, the structure of the electrode active material is largely crushed and cracked in the course of rolling an electrode active material to form an electrode, as shown in FIG. 8A. However, in the silicon-graphite composite according to one embodiment of the present invention, it can be confirmed that the structure is stably maintained even after the rolling process and the silicone is retained inside the graphite material without being exposed to the outside, as shown in FIG. 8B.

According to one embodiment of the present invention, a heat treatment may be performed in an inert atmosphere after the reassembling step such that the mechanically-reassembled silicon-graphite composite is further integrated into a single structure. This heat treatment may be performed by forming a vacuum environment inside a reaction chamber, heating the interior of the reaction chamber to a high temperature of 800° C. or more while supplying an inert gas such as Ar, N₂ or the like into the reaction chamber, and cooling the reaction chamber through air-cooling or the like.

According to one embodiment of the present invention, a surface coating step of forming an outer coating layer on the surface of the silicon-graphite composite obtained through the above-described processes may be further performed. Such a surface coating can improve electrical conductivity and can enhance the performance and that lifespan of the electrode active material according to one embodiment of the present invention and the electrode and the secondary battery having the electrode active material.

According to one embodiment of the present invention, the surface coating may be formed with a carbon material (for example, other carbon materials different from the plate-shape graphite used as a base material of the silicon-graphite composite: coal tar pitch, petroleum-based pitch, epoxy resin, phenolic resin, polyvinyl alcohol, polyvinyl chloride, ethylene, acetylene, methane or the like) on the surface of the silicon-graphite composite that forms the electrode active material. However, the surface coating layer is not necessarily essential. The electrode active material may be formed without the surface coating layer. Alternatively, an additional coating layer (conductive coating layer or the like) may be formed in addition to the aforementioned surface coating layer made of the carbon material.

Specific embodiments of the electrode active material according to the present invention.

### \textcircled{1} Embodiment 1 (GPS-1)

First, the plate-shape graphite material having an average particle size of 4 μm was prepared. Subsequently, 10 g of graphite was put into the rotary furnace. The internal atmosphere of the rotary furnace was replaced with a nitrogen atmosphere in a vacuum. Thereafter, the nitrogen having a purity of 99.999% was supplied and the temperature was increased to 580° C. After the temperature reached 580° C., SiH₄ having a purity of 99.999% was supplied for about 17 minutes and the air-cooling was performed while supplying the nitrogen having a purity of 99.999%. As a result, the silicon coating layer was coated on the plate-shape graphite. Thereafter, the plate-shape graphite on which the silicon coating layer is deposited was loaded into the spheroidization equipment and reassembling was performed. The reassembling was performed by putting the graphite material having the silicon coating layer deposited thereon into the spheroidization equipment, performing the mechanical milling at a rotation speed of 16,000 RPM for 10 minutes, providing additional graphite material into the spheroidization equipment, rotating the spheroidization equipment at a rotation speed of 7,000 RPM to mechanically reassemble the silicon-graphite composite. As a result, the silicon-graphite composite was mechanically reassembled such that the silicon coating layer is moved and positioned inside the graphite material. After the reassembling, the reassembled silicon-graphite composite was provided into the reaction chamber, and the reaction chamber was heated to 900° C. in a vacuum and an inert gas atmosphere to perform the heat treatment. Then, the air-cooling was performed.

### \textcircled{2} Embodiment 2 (GPS-2)

First, the plate-shape graphite material having an average particle size of 4 μm was prepared. Subsequently, 10 g of graphite was put into the rotary furnace. The internal atmosphere of the rotary furnace was replaced with a nitrogen atmosphere in a vacuum. Thereafter, the nitrogen having a purity of 99.999% was supplied and the temperature was increased to 580° C. After the temperature reached 580° C., SiH₄ having a purity of 99.999% was supplied for about 20 minutes and the air-cooling was performed while supplying the nitrogen having a purity of 99.999%. As a result, the silicon coating layer was coated on the plate-shape graphite. Thereafter, the plate-shape graphite on which the silicon coating layer is deposited was loaded into the spheroidization equipment and reassembling was performed. The reassembling was performed by putting the plate-shape graphite having the silicon coating layer deposited thereon into the spheroidization equipment, performing the mechanical milling at a rotation speed of 16,000 RPM for 10 minutes, providing additional graphite material into the spheroidization equipment, rotating the spheroidization equipment at a rotation speed of 7,000 RPM to mechanically reassemble the silicon-graphite composite. As a result, the silicon-graphite composite was mechanically reassembled such that the silicon coating layer is moved and positioned inside the graphite material. After the reassembling, the reassembled silicon-graphite composite was provided into the reaction chamber, and the reaction chamber was heated to 900° C. in a vacuum and an inert gas atmosphere to perform the heat treatment. Then, the air-cooling was performed.

### \textcircled{3} Embodiment 3 (GPS-3)

First, the plate-shape graphite material having an average particle size of 4 μm was prepared. Subsequently, 10 g of graphite was put into the rotary furnace. The internal atmosphere of the rotary furnace was replaced with a nitrogen atmosphere in a vacuum. Thereafter, the nitrogen having a purity of 99.999% was supplied and the temperature was increased to 580° C. After the temperature reached 580° C., SiH₄ having a purity of 99.999% was supplied for about 25 minutes and the air-cooling was performed while supplying the nitrogen having a purity of 99.999%. As a result, the silicon coating layer was coated on the plate-shape graphite. Thereafter, the plate-shape graphite on which the silicon coating layer is deposited was loaded into the spheroidization equipment and reassembling was performed. The reassembling was performed by putting the plate-shape graphite having the silicon coating layer deposited thereon into the spheroidization equipment, performing the mechanical milling at a rotation speed of 16,000 RPM for 10 minutes, providing additional graphite material into the spheroidization equipment, rotating the spheroidization equipment at a rotation speed of 7,000 RPM to mechanically reassemble the silicon-graphite composite. As a result, the silicon-graphite composite was mechanically reassembled such that the silicon coating layer is moved and positioned inside the graphite material. After the reassembling, the reassembled silicon-graphite composite was provided into the reaction chamber, and the reaction chamber was heated to 900° C. in a vacuum and an inert gas atmosphere to perform the heat treatment. Then, the air-cooling was performed.

### \textcircled{4} Comparative Example (PS)

Comparative example is the silicon-graphite composite manufactured according to the processing conditions of embodiments disclosed in Patent Document 1. In Comparative example, the silicon-graphite composite was formed by decomposing SiH₄ on a spherical graphite used as a raw material to deposit a silicon coating layer on the graphite, and then coating the petroleum-based pitch thereon.

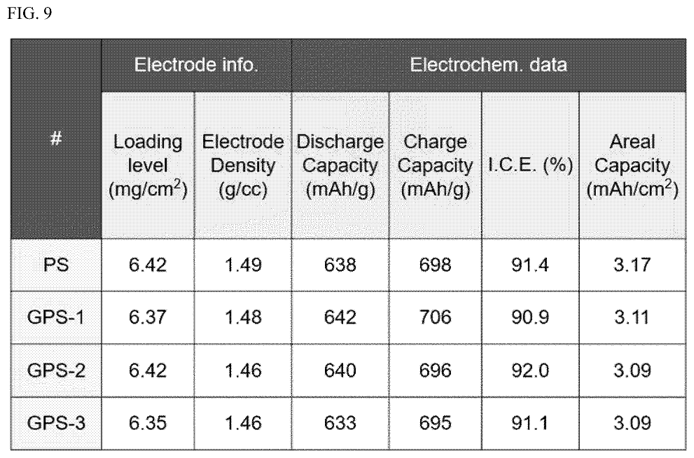

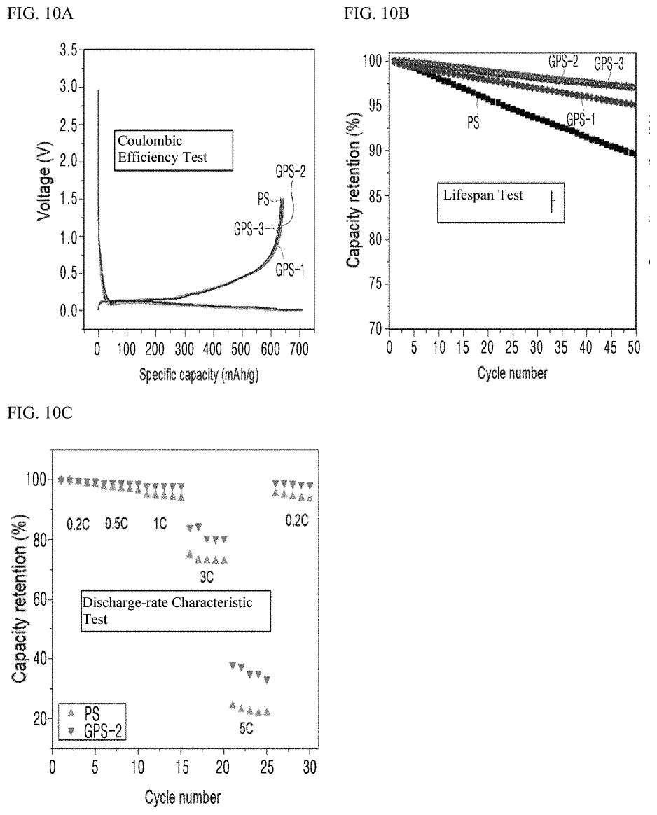

Referring to FIGS. 9 and 10, the electrode active materials manufactured according to embodiments of the present invention (the silicon-graphite composites in Embodiments 1 to 3) and the silicon-graphite composite obtained in the Comparative Example were compared in terms of performance, and the results were summarized. As shown in FIG. 9, it was confirmed that the silicon-graphite composite according to one embodiment of the present invention can provide excellent cycle characteristics while ensuring high capacity. Further, it was confirmed from the graphs of FIGS. 10A-10C that the silicon-graphite composite according to one embodiment of the present invention increases the performance of the battery without significantly reducing the lifespan of the battery due to the expansion/shrinkage of silicon regardless of the repetitive charge-discharge operation (even if silicon is added to graphite material for capacity improvement). For example, the silicon-graphite composite according to one embodiment of the present invention provides a 50-cycle cyclic retention ratio of 95% or more as shown in FIG. 10B and excellent rate-limited characteristic as shown in FIG. 10C.

Although the present invention has been described above by way of particular matters such as specific components and the like, specific embodiments and the accompanying drawings, such descriptions are merely provided for the sake of easier understanding of the present invention. The present invention is not limited to the above embodiments, but various modifications and variations may be made by those skilled in the art.

Therefore, the spirit of the present invention should not be limited to the above-described embodiments, and it should be construed that the appended claims as well as all equivalents or equivalent modifications of the appended claims will fall within the scope of the present invention.

What is claimed is:

1. Silicon-graphite composite electrode active material used for a secondary battery, wherein the silicon-graphite composite electrode active material is formed using silicon-graphite composites that silicon is mixed in graphite material as a unit powder, and wherein the silicon-graphite composite is formed such that the silicon is located inside the graphite material and the silicon is not exposed to an outer surface of the graphite material.

2. The silicon-graphite composite electrode active material for the secondary battery of claim 1, wherein the silicon included in the silicon-graphite composite is configured such that 90 wt % or more of the silicon with respect to a total weight of the silicon is located at a depth of 200 nm or more from the outer surface of the silicon-graphite composite.

3. The silicon-graphite composite electrode active material for the secondary battery of claim 1, wherein the silicon included in the silicon-graphite composite is configured such that all the silicon is located at a depth of 200 nm or more from the outer surface of the silicon-graphite composite.

4. The silicon-graphite composite electrode active material for the secondary battery of claim 1, wherein the silicon included in the silicon-graphite composite is configured to be located at a depth of 1 μm or more from the outer surface of the silicon-graphite composite.

5. The silicon-graphite composite electrode active material for the secondary battery of claim 1, wherein the silicon included in the silicon-graphite composite is configured to be located at a depth of 3 μm or more from the outer surface of the silicon-graphite composite.

6. The silicon-graphite composite electrode active material for the secondary battery of claim 2, wherein the silicon included in the silicon-graphite composite exceeds 10 wt % with respect to a total weight of the silicon-graphite composite.

7. The silicon-graphite composite electrode active material for the secondary battery of claim 6, wherein the silicon is deposited on the graphite material using a raw material gas containing at least one selected from a group consisting of SiH₄, Si₂H₆, Si₃H₈, SiCl₄, SiHCl₃, Si₂Cl₆, SiH₂Cl₂ and SiH₃Cl.

8. The silicon-graphite composite electrode active material for the secondary battery of claim 7, wherein the silicon is deposited on the graphite material by supplying the raw material gas containing at least one selected from the group consisting of SiH₄, Si₂H₆, Si₃H₈, SiCl₄, SiHCl₃, Si₂Cl₆, SiH₂Cl₂ and SiH₃Cl, together with an assist gas containing at least one selected from a group consisting of carbon, nitrogen and germanium.

9. The silicon-graphite composite electrode active material for the secondary battery of claim 8, wherein the thin film silicon layer formed on the silicon-graphite composite is formed of amorphous silicon particles or quasi-crystalline silicon particles.

10. The silicon-graphite composite electrode active material for the secondary battery of claim 9, further comprising a surface coating layer formed on an outer peripheral surface of the silicon-graphite composite.

11. A method of manufacturing silicon-graphite composite electrode active material used for secondary battery, the method comprising:
a graphite base material preparation step of preparing graphite material used as base material;
a silicon layer formation step of forming a silicon layer on the graphite base material; and
a reassembling step of spheroidizing and mechanically assembling the graphite on which the silicon layer is formed such that the silicon is located only inside the graphite.

12. The method of claim 11, wherein in the silicon layer formation step, the silicon layer is deposited and formed as a thin film layer on the graphite having a plate shape through a chemical vapor deposition.

13. The method of claim 12, wherein in the silicon layer formation step, the silicon layer is formed using a raw material gas containing at least one selected from a group consisting of SiH₄, Si₂H₆, Si₃H₈, SiCl₄, SiHCl₃, Si₂Cl₆, SiH₂Cl₂ and SiH₃Cl.

14. The method of claim 12, wherein in the silicon layer formation step, the silicon layer is formed at a thickness of 2 nm to 500 nm on the graphite base material.

15. The method of claim 14, wherein in the silicon layer formation step, the silicon layer is deposited on the graphite base material by supplying the raw material gas together with an assist gas.

16. The method of claim 15, wherein the assist gas includes at least one selected from a group consisting of carbon, nitrogen and germanium.

17. The method of claim 16, wherein the reassembling step is performed by locating the graphite base material on which the silicon layer is formed into a spheroidization equipment and then mechanically-reassembling the graphite base material on which the silicon layer is formed while rotating the spheroidization equipment at a high speed; or by locating the graphite base material on which the silicon layer is formed into a spheroidization equipment and rotating the spheroidization equipment at a high speed and then supplying additional graphite material into the spheroidization equipment and mechanically-reassembling the graphite base material on which the silicon layer is formed while rotating the spheroidization equipment at the high speed.

18. The method of claim 17, further comprising: a surface coating step of forming an outer coating layer on the surface of the silicon-graphite composite, after the reassembling step.

19. The method of claim 18, further comprising a surface modification step of modifying the surface of the graphite base material between the graphite base material preparation step and the silicon layer formation step.
